(19) United States
(12) Patent Application Publication
(10) Pub. No.: US 2024/0389291 A1
(43) Pub. Date: Nov. 21, 2024

(54) COMPONENT MOUNTING SYSTEM

(71) Applicant: YAMAHA HATSUDOKI KABUSHIKI KAISHA, Iwata-shi, Shizuoka (JP)

(72) Inventor: Hiroaki KATAI, Shizuoka (JP)

(73) Assignee: YAMAHA HATSUDOKI KABUSHIKI KAISHA, Iwata-shi, Shizuoka (JP)

(21) Appl. No.: 18/689,327

(22) PCT Filed: Sep. 10, 2021
(86) PCT No.: PCT/JP2021/033398

§ 371 Date: Mar. 5, 2024

(51) Int. Cl. H05K 13/04; H05K 13/02; H05K 13/08

(52) U.S. Cl. CPC H05K 13/0409; H05K 13/02; H05K 13/081

(57) ABSTRACT

A component mounting system includes: a mounting execution part including, a feeder, a mounting head having a suction nozzle, and a photographing camera for acquiring a processing state image showing a component suction; a storage part that accumulates and stores management data including the processing state image; a display part that displays information about the management data; and a display control part that controls the display part. When a suction error directed to the component occurs, the display control part controls the display part to display a plurality of processing state images that is most recent among processing state images showing past component suctions involving at least one of the component, the suction nozzle, the mounting head, and the feeder which are involved in the component suction of the component and are to be designated as target subjects.

### CROSS-REFERENCE TO RELATED APPLICATION

This application claims benefit of priority to International Patent Application No. PCT/JP2021/033398, filed Sep. 10, 2021, the entire contents of which are incorporated herein by reference.

### BACKGROUND

### Technical Field

The present disclosure relates to a component mounting system including a mounter that produces a component mounting board by mounting a component on a board.

### Background Art

A conventionally known component mounting system includes a mounter that produces a component mounting board by mounting an electronic component (hereinafter, referred to as just “component”) on a board, such as a printed circuit board. In the component mounting system of this type, the mounter includes: a feeder for performing a component supply of supplying a component; and a mounting head having a suction nozzle for performing a component suction of sucking the component supplied by the feeder, and performing a component mount of mounting the component on the board. The mounting head performs the component mount at each of a plurality target mounting positions set on the board in advance.

The component suction of the component by the suction nozzle may encounter an occurrence of a suction error, such as a suction failure that the suction nozzle fails to suck the component supplied by the feeder (fail to take the component out of the feeder) or that the suction nozzle having once sucked the component falls the component before mounting the component onto the board, or a suction deviation of the component with respect to the suction nozzle over a tolerance. The suction error directed to the component directly affects the quality of the component mounting board, and thus, a factor of the error is required to be rapidly specified and removed.

Japanese Unexamined Patent Publication No. 2015-135886 discloses a component mounting system that assists in a countermeasure against an occurrence of a suction error directed to a component. The component mounting system includes a countermeasure database associating a content of a suction error with a countermeasure to solve the error and provides an operator with the countermeasure against the suction error that occurs in a mounter. It is seen from this perspective that an appropriate countermeasure is rapidly adoptable in an occurrence of a suction error.

However, the component mounting system is effective on the premise that a content of a suction error and a countermeasure thereagainst are predetermined, that is, on the premise that a factor of the suction error is predetermined, and thus is not intended for assisting in specifying of a factor of an occurrence of a suction error.

### SUMMARY

Accordingly, the present disclosure provides a technology of assisting in specifying of a factor of an occurrence of a suction error when the suction error occurs in a component suction by a suction nozzle in a component mounting system including a mounter.

A component mounting system according one aspect of the present disclosure includes a mounting execution part including: a feeder for performing a component supply of supplying a component; a mounting head having a suction nozzle for performing a component suction of sucking the component, and performing a component mount of mounting the component sucked by the suction nozzle on a board; and a photographing camera for acquiring a processing state image showing the component suction; a storage part that accumulates and stores management data including the processing state image showing the component suction; a display part that displays information about the management data; and a display control part that controls the display part. When a suction error occurs in the component suction of the component by the suction nozzle, the display control part controls the display part to display a plurality of processing state images that is most recent among processing state images showing past component suctions involving at least one of the component, the suction nozzle, the mounting head, and the feeder which are involved in the component suction of the component and are to be designated as target subjects.

### BRIEF DESCRIPTION OF THE DRAWINGS

FIG. 1 is a block diagram showing a configuration of a component mounting system according to an embodiment of the present disclosure.

FIG. 2 is a plan view of a mounter main body of a mounter included in the component mounting system.

FIG. 3 is an enlarged front view of a head unit included in the mounter main body and a periphery therearound.

FIG. 4 is a block diagram showing a configuration of a management device included in the component mounting system.

FIG. 5 is an illustration of an example of a display screen image displayed on a mounting display part.

FIG. 6 is a schematic view showing an example of an image group of processing state images or suction processing images showing a component suction displayed on the display screen image in FIG. 5; and

FIG. 7 is a schematic view showing another example of an image group of processing state images or suction processing images showing a component suction.

### DETAILED DESCRIPTION

Hereinafter, a preferable embodiment of the present disclosure will be described with reference to the accompanying drawings.

### Configuration of a Component Mounting System

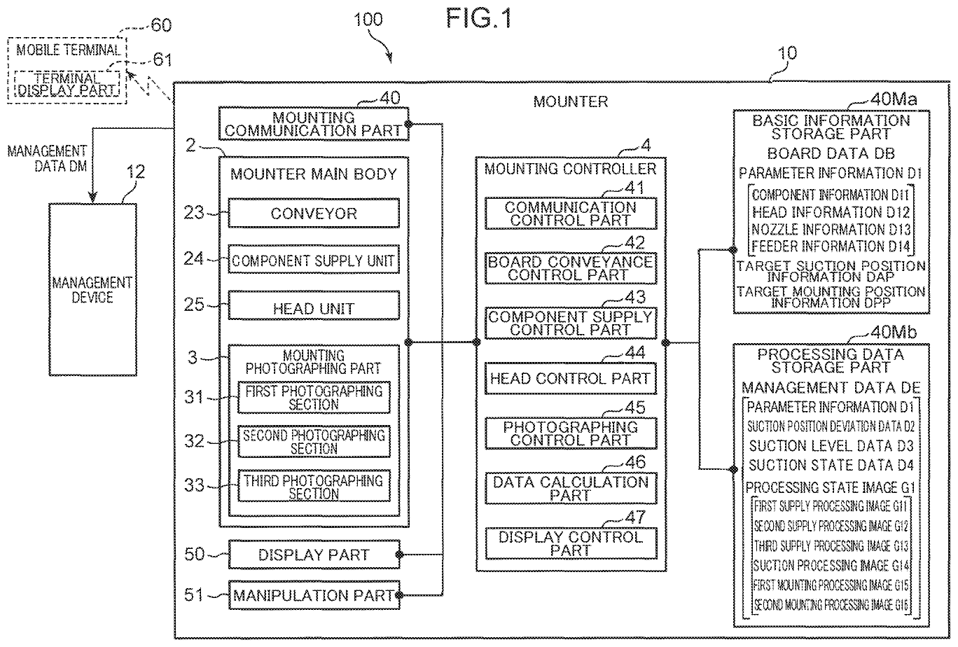

FIG. 1 is a block diagram showing a component mounting system according to an embodiment of the present disclosure. A component mounting system 100 includes a mounter 10 and a management device 12 connected to the mounter 10 for data communication therewith. The mounter 10 is a device that mounts an electronic component (hereinafter, referred to as a “component”) on a board P, such as a printed circuit board.

The mounter 10 establishes a component mounting line for producing a component mounting board by mounting a component on the board P in cooperation with a soldering printing device, a reflow device, and an inspection device (each of which is not shown). The soldering printing device prints soldering paste at a component mounting portion on the board P. The reflow device performs a reflow of melting the soldering paste on the board P bearing the component mounted thereon, and hardening the soldering paste thereafter. The inspection device inspects a component mounting state on the board P after the reflow.

The soldering printing device, the mounter 10, the reflow device, and the inspection device are linearly connected to one another in this order. The soldering printing device, the reflow device, and the inspection device are connected to the management device 12 for data communication therewith in the same manner as the mounter 10.

As shown in FIG. 1, the mounter 10 includes a mounter main body 2 (corresponding to a “mounting execution part” in the present disclosure), a mounting controller 4, a mounting communication part 40, a basic information storage part 40Ma, a processing data storage part 40Mb, a mounting display part 50, and a mounting manipulation part 51. The mounter main body 2 performs a component mounting process of mounting a component on the board P. The mounting communication part 40 includes an interface for data communication with the management device 12 and serves to output various kinds of data and information to the management device 12. The mounting controller 4 controls the component mounting process by the mounter main body 2 in accordance with board data BD stored in the basic information storage part 40Ma and controls the data communication of the mounting communication part 40. The processing data storage part 40Mb stores the various kinds of data and images acquired in a sequence of the component mounting process in the mounter main body 2. The mounting display part 50 displays various kinds of information about the component mounting process. The mounting manipulation part 51 receives an input manipulation of each kind of instruction from an operator to the mounting controller 4. Hereinafter, each part will be described in detail.

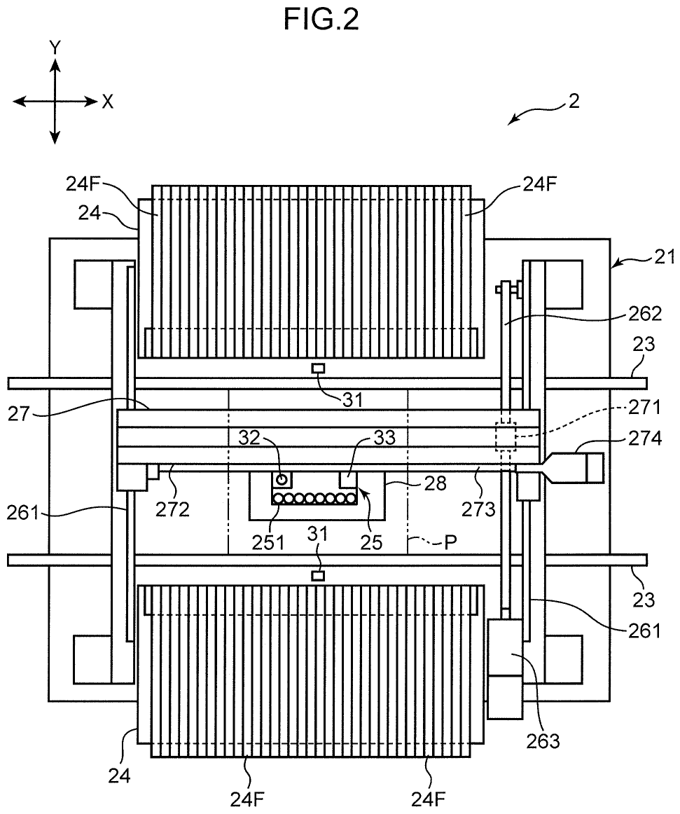

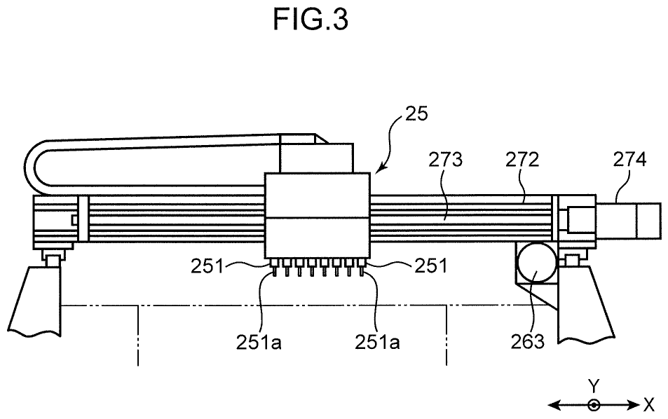

FIG. 2. is a plan view of the mounter main body 2. FIG. 3 is an enlarged front view of a head unit 25 included in the mounter main body 2 and a periphery therearound, the head unit 25 being described later. Each of FIG. 2 and FIG. 3 shows a directional relation by using an XY-rectangular coordinate system having axes perpendicularly intersect with each other on a horizontal plane.

The mounter main body 2 includes a main body frame 21, a conveyor 23, a component supply unit 24, the head unit 25, and a board support unit 28. The main body frame 21 is an assembly including each part constituting the mounter main body 2, and has a substantially rectangular shape in a plan view in a direction (vertical direction) perpendicularly intersecting both the X-direction and the Y-direction. The conveyor 23 is a conveyance mechanism arranged on the main body frame 21 for conveying the board P. The conveyor 23 extends in the X-direction. The board P is conveyed along the conveyor 23 in the X-direction and set at a predetermined working position by the board support unit 28. The board support unit 28 supports the board P from below to set the board P at a position on the conveyor 23.

The component supply unit 24 includes a region for arranging a plurality of feeders 24F attached thereto side by side, and is provided at each of the opposite ends of the main body frame 21 in the Y-direction across the conveyor 23. Each feeder 24F is a device for performing a component supply of supplying a component. Examples of the feeder 24F include a tape feeder. The tape feeder includes a reel on which a component accommodation tape accommodating components at predetermined intervals is wound, and sends out the component accommodation tape from the reel to supply each component at a predetermined component supply position. The feeder 24F attached to the component supply unit 24 is not limited to the tape feeder and may be a feeder of another type.

The head unit 25 picks up a component from an associated feeder 24F of the component supply unit 24 and moves to the working position to mount the component onto the board P. The head unit 25 is held by a movable frame 27. The main body frame 21 bears thereon a pair of retaining rails 261 extending in the Y-direction and a ball screw shaft 262 to be rotatably driven by a Y-axis servo motor 263. The movable frame 27 is located on the retaining rails 261, and the movable frame 27 is provided with a nut 271 screwed with the ball screw shaft 262. The movable frame 27 is provided with a guide member 272 extending in the X-direction and a ball screw shaft 273 to be driven by an X-axis servo motor 274. The guide member 272 holds the head unit 25 movably, and the head unit 25 is provided with a nut screwed with the ball screw shaft 273.

That is to say, the movable frame 27 is driven by the Y-axis servo motor 263 to move in the Y-direction, and the head unit 25 is driven by the X-axis servo motor 274 to move in the X-direction with respect to the movable frame 27. Therefore, the head unit 25 is movable in the Y-direction along with the movement of the movable frame 27 and movable in the X-direction along the movable frame 27. This configuration allows the head unit 25 to move between the component supply unit 24 and the board P being at the working position.

As shown in FIG. 3, the head unit 25 includes a plurality of mounting heads 251. Each of the mounting heads 251 has a suction nozzle 251a at a distal end or lower end thereof. The suction nozzle 251a can suck and hold a component supplied by an associated feeder 24F. The suction nozzle 251a performs a component suction of sucking the component. The suction nozzle 251a is communicable with at least one of a negative pressure generator, a positive pressure generator, and the atmosphere via an electric switch valve. Specifically, a supply of a negative pressure to the suction nozzle 251a enables the suction nozzle 251a to suck and hold the component, and a supply of a positive pressure thereafter results in releasing the sucking and holding of the component. Each mounting head 251 performs a component mount of mounting a component sucked and held by a relevant suction nozzle 251a on the board P suitably at a corresponding one of target mounting positions set on the board P.

The mounting head 251 is shiftable upward and downward in a vertical direction with respect to a frame of the head unit 25 and rotatable about a head axis extending in the vertical direction. The mounting head 251 is shiftable upward and downward between a suction available position where the suction nozzle 251a can suck and hold the component and a retraction position located above the suction available position. In other words, in picking up the component from the feeder 24F, the mounting head 251 shifts downward from the retraction position to the suction available position to suck and hold the component, and thereafter shifts upward from the suction available position to the retraction position. The mounting head 251 is further shiftable upward and downward between a mount available position for mounting the component sucked and held by the suction nozzle 251a at a target mounting position on the board P and the retraction position. In other words, in mounting the component onto the board P, the mounting head 251 shifts downward from the retraction position to the mount available position to release the component on the board P, and thereafter shifts upward from the mount available position to the retraction position.

As shown in FIG. 1 and FIG. 2, the mounter main body 2 further includes a mounting photographing part 3. The mounting photographing part 3 performs a photographing operation of photographing a photographing subject to acquire a photographing image. The mounting photographing part 3 includes a first photographing section 31, a second photographing section 32, and a third photographing section 33.

Each of the first photographing section 31, the second photographing section 32, and the third photographing section 33 is a photographing camera including an image sensor, e.g., a complementary metal-oxide-semiconductor (CMOS) or a charged-coupled device (CCD).

The first photographing section 31 is located between the component supply unit 24 and the conveyor 23 on the main body frame 21. After execution of a component suction by a suction nozzle 251a of each associated mounting head 251, the first photographing section 31 photographs a component sucked and held by the suction nozzle 251a from below while the head unit 25 passes above the first photographing section 31 in movement from the component supply unit 24 to a position above the board P being at a working position. An image referred to as a suction processing image G14 and obtained in this manner shows a processing state of the component suction by the suction nozzle 251a, and is included in a processing state image G1 acquired in the mounter main body 2. The suction processing image G14 enables a check of a processing state of the component suction, such as a suction failure directed to the component by the suction nozzle 251a, and further, e.g., a posture of the component sucked by the suction nozzle 251a, or a deviation amount of a suction position of the component with respect to the suction nozzle 251a. The suction failure directed to the component represents a processing state where the suction nozzle 251a fails to suck and hold the component supplied from the feeder 24F, or once sucks and holds the component but falls the component thereafter. In this case, a suction processing image G14 only showing the suction nozzle 251a is acquired. The suction processing image G14 is input to the mounting controller 4 to be described later for use in calculation of a suction position deviation by a data calculation part 46.

The second photographing section 32 photographs a component supply position for the feeder 24F from obliquely above in a state where the head unit 25 is arranged in such a manner that the suction nozzle 251a is located directly above the component supply position set by the feeder 24F. Specifically, the second photographing section 32 acquires an image referred to as a first supply processing image G11 and obtained by photographing the component supplied at the component supply position by the feeder 24F from obliquely above before the suction nozzle 251a performs a sucking operation. The second photographing section 32 further acquires an image referred to as a second supply processing image G12 and obtained in the sucking operation by the suction nozzle 251a for the component supplied at the component supply position by the feeder 24F, e.g., obtained in a state at the component supply position when the mounting head 251 is located at the suction available position. Besides, the second photographing section 32 acquires an image referred to as a third supply processing image G13 and obtained by photographing a state at the component supply position after a finish of the suction operation by the suction nozzle 251a.

Each of the first supply processing image G11, the second supply processing image G12, and the third supply processing image G13 shows a processing state of a component supply by the feeder 24F and is included in the processing state image G1 acquired in the mounter main body 2. Each of the first supply processing image G11, the second supply processing image G12, and the third supply processing image G13 enables a check of, for example, a posture of a component supplied at a component supply position for the feeder 24F and sucking performance by the suction nozzle 251a for the component at the component supply position.

The second photographing section 32 photographs a target mounting position set on the board P obliquely from above in a state where the head unit 25 is arranged in such a manner that the suction nozzle 251a sucking and holding a component is located directly above the target mounting position. Specifically, the second photographing section 32 acquires an image referred to as a first mounting processing image G15 and obtained by photographing the target mounting position on the board P from obliquely above before the mounting head 251 mounts the component sucked by the suction nozzle 251a on the board P. Furthermore, the second photographing section 32 acquires an image referred to as a second mounting processing image G16 and obtained by photographing a state at the target mounting position after a finish of the component mounting operation by the mounting head 251.

Each of the first mounting processing image G15 and the second mounting processing image G16 shows a processing state of a component mount by the mounting head 251, and is included in the processing state image G1 acquired in the mounter main body 2. Each of the first mounting processing image G15 and the second mounting processing image G16 enables a check of a processing state of the component mount, e.g., a posture of the component mounted at the target mounting position on the board P.

The third photographing section 33 is arranged at the head unit 25. The board P at the working position has an upper surface provided with various kinds of marks, and the third photographing section 33 photographs each kind of mark from above to recognize the mark in execution of the component mount by the mounting head 251. The recognition of the mark on the board P by the third photographing section 33 leads to detection of a position deviation amount to an origin coordinate of the board P.

As aforementioned, the suction processing image G14 acquired by the first photographing section 31 shows a processing state of the component suction. Each of the first supply processing image G11, the second supply processing image G12, and the third supply processing image G13 acquired by the second photographing section 32 shows a processing state of the component supply by the feeder 24F, and further enables a check of the suction performance by the suction nozzle 251a for the component at the component supply position as described above, and thus is said to show a processing state of the component suction as well. In other words, in this example, each of the suction processing image G14, the first supply processing image G11, the second supply processing image G12, and the third supply processing image G13 corresponds to a “processing state image showing the component suction” in the present disclosure. Besides, each of the first photographing section 31 and the second photographing section 32 corresponds to a “photographing camera” in the present disclosure.

The basic information storage part 40Ma stores the board data BD to be referred to by the mounting controller 4. The board data BD includes: a plurality of pieces of parameter information D1 necessary for the mounting controller 4 to control the component mounting process in the mounter main body 2; target suction position information DAP; and target mounting position information DPP. The parameter information D1 includes component information D11, head information D12, nozzle information D13, and feeder information D14.

The component information D11 has registration of parameters for specifying a type of a component, including a component name showing a kind of the component, an outer dimension of the component in each of the X-direction and the Y-direction, and a thickness of the component. The head information D12 has registration of a parameter for specifying a type of the mounting head 251. The head information D12 has registration of parameters for specifying the type of the mounting head 251, including the serial number of the mounting head 251. The nozzle information D13 has registration of a parameter for specifying a type of the suction nozzle 251a. The nozzle information D13 has registration of parameters for specifying the type of the suction nozzle 251a, including a kind of the suction nozzle 251a and an identifier of the suction nozzle 251a. The feeder information D14 has registration of a parameter for specifying a type of the feeder 24F. The feeder information D14 has registration of parameters for specifying the type of the feeder 24F, including a kind of the feeder 24F and a set position of the feeder 24F in the component supply unit 24.

The target suction position information DAP has registration of a parameter including a suction position or target suction position at sucking of the component by the suction nozzle 251a. The target suction position information DAP has registration of a parameter including a coordinate of the target suction position of the component to the suction nozzle 251a in each of the X-direction and the Y-direction. The target suction position is typically set at a center on a sucked face of the component. The target mounting position information DPP has registration of a parameter including a target mounting position set on a pattern forming board PP for the component. The target mounting position information DPP has registration of a parameter including a coordinate of the target mounting position on the board P in each of the X-direction and the Y-direction.

The processing data storage part 40Mb accumulates and stores manage data DM associating the processing state image G1 acquired by the mounting photographing part 3 with each kind of data related to the processing state image G1. Specifically, the processing data storage part 40Mb accumulates and stores the management data DM associating: the suction processing image G14 acquired by the first photographing section 31; the first supply processing image G11, the second supply processing image G12, the third supply processing image G13, the first mounting processing image G15, and the second mounting processing image G16 each acquired by the second photographing section 32; the parameter information D1; and suction position deviation data D2, suction level data D3, and suction state data D4 to be described later with one another.

Although the details will be described later, the suction position deviation data D2, the suction level data D3, and the suction state data D4 is acquired by the data calculation part 46 to be described later per component mount by the mounting head 251. In execution of one component mount by the mounting head 251, one kind of component among a plurality of kinds of components is used, one mounting head 251 among a plurality of mounting heads 251 is used, one suction nozzle 251a among a plurality of suction nozzles 251a is used, and one feeder 24F among a plurality of feeders 24F is used. In other words, each of the component, the mounting head 251, the suction nozzle 251a, and the feeder 24F to be used is uniquely determined per component mount by the mounting head 251. Further, each of the photographing section 31 and the second photographing section 32 acquires a processing state image G1 per component mount by the mounting head 251. Consequently, the suction position deviation data D2, the suction level data D3, and the suction state data D4 acquired by the data calculation part 46 per component mount by the mounting head 251; the parameter information D1; and the processing state image G1 are associated with one another.

The processing data storage part 40Mb includes, for example, a solid state drive (SSD). In a case where the processing data storage part 40Mb includes the SSD, the processing data storage part 40Mb accumulates and stores the management data DM concerning the component mount. When the amount of the management data DM exceeds a storage capacity of the SSD, the management data DM is sequentially sent to the management device 12 in a chronologically old order. In this case, such chronologically old management data DM is deleted from the processing data storage part 40Mb.

The mounting display part 50 includes, for example, a liquid crystal display. The mounting display part 50 displays various kinds of information about the component mounting process in the mounter main body 2. The various kinds of information include information about the management data DM stored in the processing data storage part 40Mb. A display operation of the mounting display part 50 is controlled by a display control part 47 to be described later.

The mounting manipulation part 51 (corresponding to an “instruction input part” in the present disclosure) includes, for example, a keyboard, a mouse, or a touch screen provided to the mounting display part 50. The mounting manipulation part 51 receives an input manipulation of each kind of instruction from an operator to the mounting controller 4. The input manipulation includes an input manipulation of each kind of instruction about a display mode of the mounting display part 50.

The mounting controller 4 includes a central processing unit (CPU), a read only memory (ROM) storing a control program, a random access memory (RAM) for use as a work area of the CPU, and the like. The mounting controller 4 controls an operation of each constituent element of the mounter main body 2, controls a data communication operation of the mounting communication part 40, and further executes various kinds of calculations in response to execution of the control program stored in the ROM by the CPU. The mounting controller 4 controls the operation of each constituent element of the mounter main body 2 in accordance with the board data BD stored in the basic information storage part 40Ma. The mounting controller 4 includes, as main operative configurations, a communication control part 41, a board conveyance control part 42, a component supply control part 43, a head control part 44, a photographing control part 45, the data calculation part 46, and the display control part 47.

The communication control part 41 controls the mounting communication part 40 to control data communication between the mounter 10 and the management device 12. The mounting communication part 40 is controlled by the communication control part 41 to send the management data DM stored in the processing data storage part 40Mb to the management device 12. As aforementioned, in the case where the processing data storage part 40Mb includes the SSD, the mounting controller 4 sequentially sends, to the management device 12, chronologically old management data DM among the management data DM stored in the processing data storage part 40Mb.

The board conveyance control part 42 controls an operation of conveying the board P by the conveyor 23. The component supply control part 43 controls a component supply by each of the feeders 24F arrayed in the component supply unit 24 in accordance with the component information D11 and the feeder information D14 in the board data BD. The head control part 44 controls the mounting head 251 by controlling the head unit 25 in accordance with the component information D11, the head information D12, the nozzle information D13, the target suction position information DAP, and the target mounting position information DPP each included in the board data BD. In this manner, the head control part 44 causes the mounting head 251 to execute the component mount of mounting the component sucked and held by the suction nozzle 251a on the board P at corresponding one of the target mounting positions set on the board P. The photographing control part 45 controls a photographing operation by each of the first photographing section 31, the second photographing section 32, and the third photographing section 33 constituting the mounting photographing part 3.

The data calculation part 46 recognizes an actual suction position of the component by the suction nozzle 251a on the basis of the suction processing image G14 acquired by the first photographing section 31, and calculates a position deviation of the recognized actual suction position with respect to the target suction position shown in the target suction position information DAP. The data calculation part 46 acquires suction position deviation data D2 indicating an amount of the position deviation between the actual suction position and the target suction position per component mount by the mounting head 251. The suction position deviation data D2 acquired by the data calculation part 46 indicates a deviation amount of the suction position of the component with respect to the suction nozzle 251a in the component suction.

The data calculation part 46 acquires data indicating a negative pressure level of the negative pressure generator connected to the suction nozzle 251a as suction level data D3 indicating a component suction level of the suction nozzle 251a in the component suction. At this time, the data calculation part 46 acquires the suction level data D3 per component mount by the mounting head 251.

The data calculation part 46 further acquires suction state data D4 indicating whether a suction state of the component by the suction nozzle 251a in the component suction is appropriate per component mount by the mounting head 251 on the basis of the suction processing image G14 acquired by the first photographing section 31 and the data indicating the negative pressure level of the negative pressure generator connected to the suction nozzle 251a.

Specifically, under the conditions that the suction processing image G14 acquired by the first photographing section 31 enables recognition of the component, the suction position deviation data D2 falls within a permissible range, and that the negative pressure level of the negative pressure generator falls within a permissible range in the component suction by the suction nozzle 251a, the data calculation part 46 acquires the suction state data D4 additionally including suction appropriate information indicating that the suction state of the component by the suction nozzle 251a is appropriate. By contrast, when one of the three conditions described above is not satisfied, that is, when the suction processing image G14 acquired by the first photographing section 31 fails recognition of the component, the suction position deviation data D2 is out of the permissible range, or the negative pressure level of the negative pressure generator is out of the permissible range, the data calculation part 46 acquires suction state data D4 additionally including suction inappropriate information.

The suction position deviation data D2, the suction level data D3, and the suction state data D4 acquired by the data calculation part 46 per component mount is stored as the management data DM in the processing data storage part 40Mb in association with the parameter information D1 and the processing state image G1.

When the data calculation part 46 acquires the suction state data D4 additionally including the suction inappropriate information, i.e, when an error (hereinafter, just referred to as a “suction error” as well) occurs in a component suction, the component supply control part 43 suspends an operation of each of the feeders 24F arrayed in the component supply unit 24, and the head control part 44 suspends an operation of the head unit 25. This results in suspending the component mounting process in the mounter main body 2. The suspended component mount process is resumed in response to an input of a predetermined resumption manipulation from an operator via the mounting manipulation part 51.

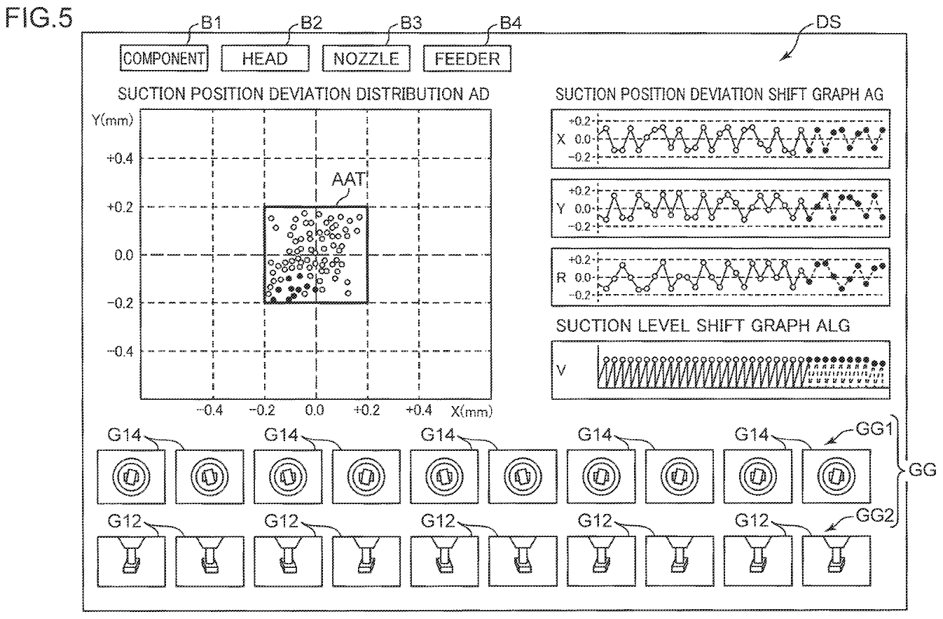

The display control part 47 controls the mounting display part 50 to display various kinds of information and images depending on a situation of the component suction or the component mount in the mounter main body 2. In particular, as aforementioned, when the data calculation part 46 acquires the suction state data D4 additionally including the suction inappropriate information, that is, when an error occurs in the component suction, the display control part 47 gives a notification of the occurrence of the error and controls the mounting display part 50 to display a predetermined display screen image DS (FIG. 5) to assist in specifying of a factor of the occurrence of the suction error on the basis of an input manipulation from an operator for a display request. The display screen image DS will be described in detail later.

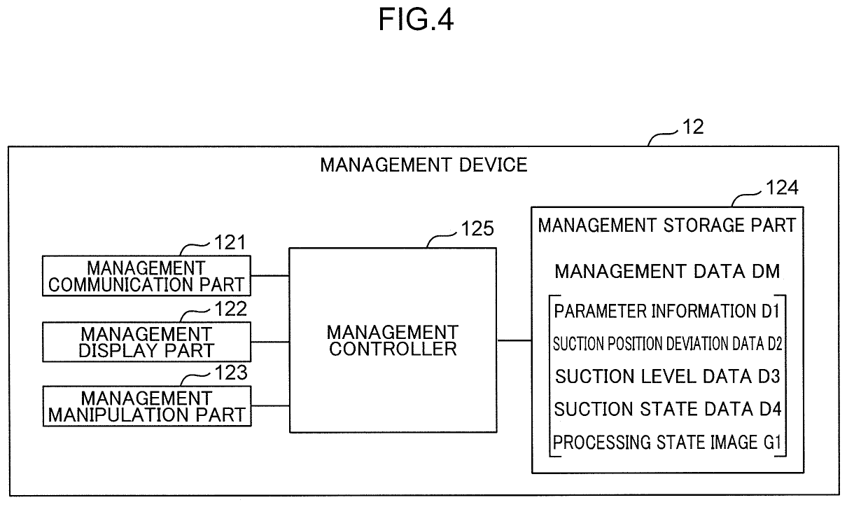

The management device 12 includes, for example, a personal computer communicably connected to the mounter 10 for data communication therewith. FIG. 4 is a block diagram showing a configuration of the management device 12. The management device 12 includes a management communication part 121, a management display part 122, a management manipulation part 123, a management storage part 124, and a management controller 125.

The management communication part 121 includes an interface for data communication with the mounter 10. The management communication part 121 acquires management data DM input from the mounter 10. The management storage part 124 accumulates and stores the management data DM acquired by the management communication part 121. The management display part 122 includes, for example, a liquid crystal display. The management display part 122 displays information about the management data DM stored in the management storage part 124. The management controller 125 controls a display operation of the management display part 122.

The management manipulation part 123 includes, for example, a keyboard, a mouse, or a touch screen provided at the management display part 122. The management manipulation part 123 receives an input manipulation of each kind of instruction from the operator about displaying on the management display part 122. The management controller 125 controls the management display part 122 in accordance with the instruction input to the management manipulation part 123. Display control of the mounting display part 50 by the display control part 47

When an error occurs in a component suction and an operator performs an input manipulation for a display request, the display control part 47 controls the mounting display part 50 to display the display screen image DS shown in FIG. 5 as a screen image to assist in specifying of a factor of the occurrence of the suction error as described above.

Specifically, the display control part 47 makes the display screen image DS display, on the basis of each piece of management data DM stored in the processing data storage part 40Mb, one or more kinds of image groups GG each including chronologically arranged processing state images G1 that are most recent in component suctions (most recent ten suctions in the example) among processing state images G1 showing past component suctions for a component which is the same as the component involved in a component suction in which a suction error occurs and has the same component information D11 as the component, i.e., the component directed to the occurrence of the suction error. In this example, the display control part 47 executes the displaying of an image group GG1 of suction processing images G14 acquired by the first photographing section 31 and chronologically arrayed in a row in a left-right direction and an image group GG2 of the second supply processing images G12 acquired by the second photographing section 32 and chronologically arrayed in a row in the left-right direction respectively at two upper and lower tiers. In this case, the display control part 47 executes the displaying of the image groups GG1, GG2 in such a manner that their respective images obtained in the same component suction are located in a correspondence in the upper and lower tiers. In the example in FIG. 5, the second image group GG2 of the second supply processing images G12 is displayed under the image group GG1 of the suction processing images G14. Each of the images G12, G14 located closer to the right respectively in the image groups GG1, GG2 is chronologically newer.

The operator thus can specify, on the basis of the image groups GG1, GG2 on the display screen image DS, a factor of the occurrence of the suction error by checking the most recent suction processing images G12, G14 of the same component.

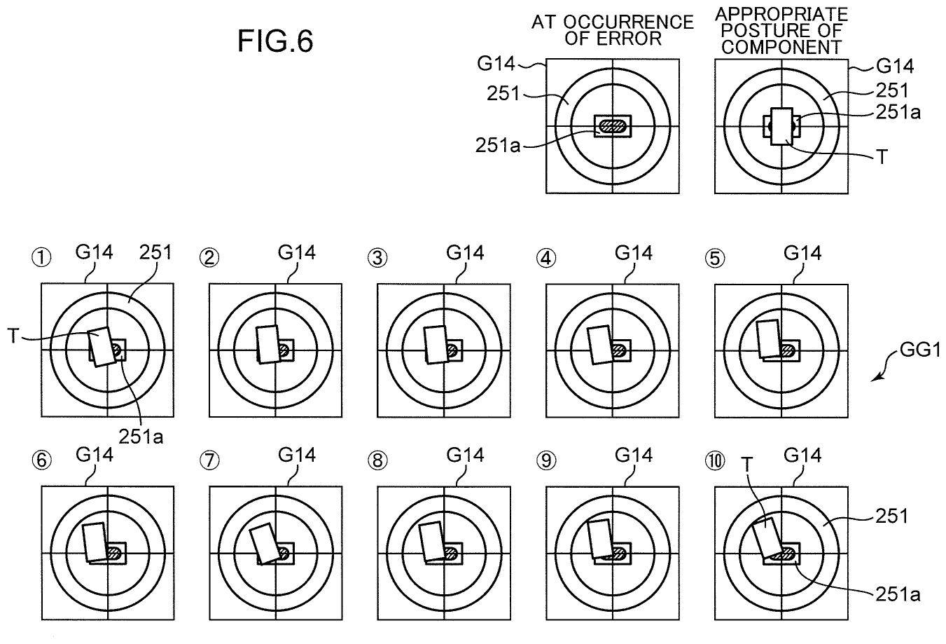

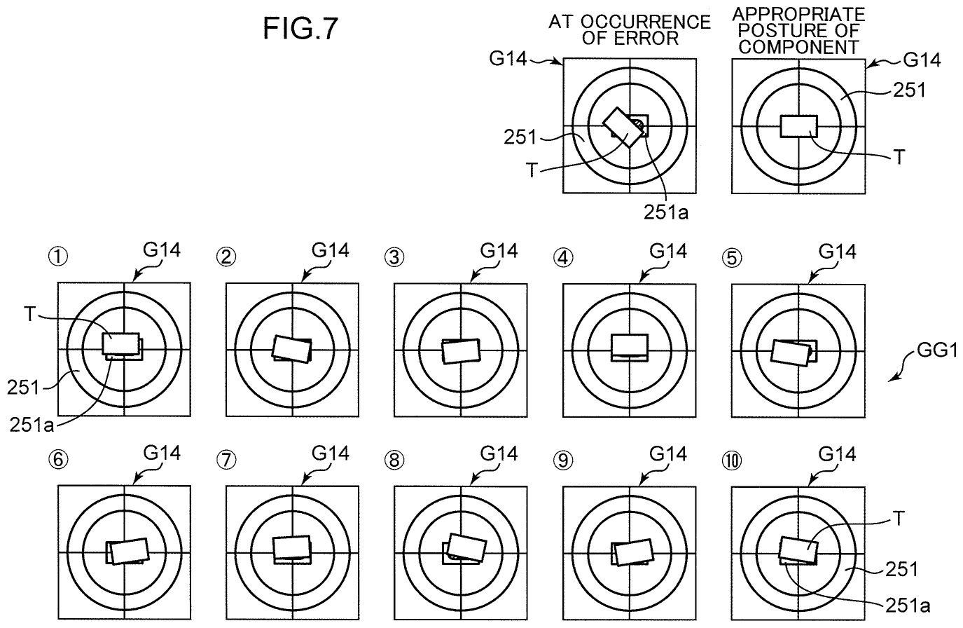

Each of FIG. 6 and FIG. 7 schematically shows an example of the image group GG1 of the suction processing images G14 displayed on the display screen image DS. Each drawing shows the image group GG1 in two rows for convenience. A smaller value of a circled number denotes a chronologically older image. Each of FIG. 6 and FIG. 7 shows, at upper right positions thereof, a reference suction processing image G14 in an occurrence of a suction error and a reference suction processing image G14 in appropriate sucking and holding of a component.

The example in FIG. 6 shows a state of an occurrence of a suction failure that the suction nozzle 251a fails to suck and hold a component as a suction error. In this example, a component T has a tendency of generally being sucked in a specific direction, i.e., upper leftward in FIG. 6, with respect to a sucking and holding face of the suction nozzle 251a, and a deviation amount thereof gradually increases. From this perspective, the operator can specify the relative deviation of the target suction position by the suction nozzle 251a at the component suction to the component supply position for the feeder 24F as one factor of the suction error.

The example in FIG. 7 shows a state where a position deviation amount of a component T with respect to the suction nozzle 251a is out of a permissible range as suction error. This example shows a variation in positions and postures of the component T with respect to the suction nozzle 25 la per component suction, and thus, no specific tendency is seen in the position deviation. From this perspective, the operator can specify an occurrence of mismatching between the component T and the suction nozzle 251a or nozzle clogging in the suction nozzle 251a as one factor of weakness of the force of sucking the component T by the suction nozzle 251a.

Referring back to FIG. 5, the display control part 47 further controls the mounting display part 50 to display, on the display screen image DS, a suction position deviation distribution AD together with the image group GG on the basis of each piece of management data DM stored in the processing data storage part 40Mb, the suction position deviation distribution showing a distribution according to a data group for a component which is the same as the component directed to the occurrence of the suction error among data groups each including the suction position deviation data D2 included in the management data DM. The suction position deviation distribution AD is expressed by, for example, an “XY-deviation distribution” showing a distribution of position deviations in the X-coordinate and the Y-coordinate concerning a position deviation amount of the actual suction position of the component to the suction nozzle 251a shown in the suction position deviation data D2 with respect to the target suction position.

In this case, the display control part 47 executes displaying of a permissible range AAT of the deviation amount of the suction position of the component with respect to the suction nozzle 251a in the suction position deviation distribution AD. The display control part 47 further controls the mounting display part 50 to display specific suction position deviation data D2 associated with the image group GG among data groups each including suction position deviation data D2 in a display mode different from a mode for the remaining suction position deviation data D2. For instance, the display control part 47 controls the mounting display part 50 to display the suction position deviation data D2 associated with the image group GG in a color different from a color for displaying the remaining suction position deviation data D2. In the example in FIG. 5, a plot for the suction position deviation data D2 associated with the image group GG is displayed in black and a plot for the remaining suction position deviation data D2 is displayed in white.

Besides, the display control part 47 controls the mounting display part 50 to display a suction position deviation shift graph AG together with the image group GG on the display screen image DS. The suction position deviation shift graph AG shows a chronological shift according to a data group including the suction position deviation data D2 constituting the suction position deviation distribution AD. The suction position deviation shift graph AG relates to a suction position deviation amount of a component with respect to the suction nozzle 251a, and includes a graph showing a chronological shift of a deviation amount in the X-direction, a graph showing a chronological shift of a deviation amount in the Y-direction, and a graph showing a chronological shift of a deviation amount in an R-direction, i.e., a rotation direction. The display control part 47 controls the mounting display part 50 to display specific suction position deviation data D2 associated with the image group GG among data groups each including suction position deviation data D2 constituting the suction position deviation shift graph AG in a display mode different from a mode for the remaining suction position deviation data D2, in this case as well. For instance, the display control part 47 controls the mounting display part 50 to display the suction position deviation data D2 associated with the image group GG in a color different from a color for displaying the remaining suction position deviation data D2. In the example in FIG. 5, the suction position deviation data D2 associated with the image group GG is displayed in black and the remaining suction position deviation data D2 is displayed in white. Further, the suction position deviation shift graph AG has a portion corresponding to the image group GG and denoted by a dashed line and another portion denoted by a solid line.

The display control part 47 additionally controls the mounting display part 50 to display a suction level shift graph ALG together with the image groups GG1, GG2 on the display screen image DS. The suction level shift graph ALG shows a chronological shift according to a data group for a component which is the same as the component involved in a component suction in which a suction error occurs among data groups each including suction level data D3 included in the management data DM stored in the processing data storage part 40Mb. In this case, the display control part 47 controls the mounting display part 50 to display specific suction level data D3 associated with the image group GG among the data groups each including the suction level data D3 constituting the suction level shift graph ALG in a display mode different from a display mode for the remaining suction level data D3. For instance, the display control part 47 controls the mounting display part 50 to display the suction level data D3 associated with the image group GG in a color different from a color for displaying the remaining suction level data D3. In the example in FIG. 5, the suction level data D3 associated with the image group GG is displayed in black and the remaining suction level data D3 is displayed in white. Further, the suction level shift graph ALG has a portion corresponding to the image group GG and denoted by a dashed line and another portion denoted by a solid line.

Displaying of the suction position deviation distribution AD, the suction position deviation shift graph AG, and the suction level shift graph ALG on the display screen image DS allows the operator to confirm, on the basis of the suction position deviation distribution AD, a situation of an occurrence of a position deviation of an actual suction position of a component which is the same as the component directed to an occurrence of a suction error, and further confirm, on the basis of the suction position deviation shift graph AG, a chronological shift of the position deviation. Moreover, a chronological shift according to the suction level data D3 can be confirmed on the basis of the suction level shift graph ALG. In this manner, the operator can narrow down a factor of an occurrence of a suction error and determine as to whether the suction error unexpectedly occurs by confirming a situation of an occurrence of the position deviation of the actual suction position, a chronological shift of the position deviation, and the chronological shift of the suction level together with the image group GG. In this case, regarding the suction position deviation distribution AD and the suction position deviation shift graph AG, suction position deviation data D2 associated with an image group GG is displayed in a display mode different from a display mode for the remaining suction position deviation data D2. Regarding the suction level shift graph ALG, suction level data D3 associated with the image group GG is displayed in a display mode different from a display mode for the remaining suction level data D3. The displaying way clarifies a correspondence between the suction position deviation data D2 and the image group GG in each of the suction position deviation distribution AD and the suction position deviation shift graph AG, and a correspondence between the suction level data D3 and the image group GG in the suction level shift graph ALG. This enables the operator to reliably grasp the correspondence between the image group GG and each of the suction position deviation data D2 and the suction level data D3, and contributes to specifying of the factor of the occurrence of the suction error.

The display control part 47 controls the mounting display part 50 to display the display screen image DS so as to include a component designation region B1, a head designation region B2, a nozzle designation region B3, and a feeder designation region B4, each accepting a manual input via the mounting manipulation part 51. Each of the designation regions B1 to B4 receives an input of an instruction of designating a target subject among a “component”, a “mounting head”, a “suction nozzle”, and a “feeder” for an image group GG, a suction position deviation distribution AD, a suction position deviation shift graph AG, and a suction level shift graph ALG to be displayed on the display screen image DS. The display control part 47 controls the mounting display part 50 to display the image group GG, the suction position deviation distribution AD, the suction position deviation shift graph AG, and the suction level shift graph ALG for the target subject designated via the mounting manipulation part 51, on the display screen image DS.

Specifically, when the “component” is designated as a target subject, the display control part 47 controls the mounting display part 50 to display the image group GG, the suction position deviation distribution AD, the suction position deviation shift graph AG, and the suction level shift graph ALG with a focus on a component which is the same as the component involved in a component suction in which a suction error occurs, i.e., a component having the same component information D11 as the component directed to the occurrence of the suction error, as described above. When the “mounting head” is designated as a target subject, the display control part 47 controls the mounting display part 50 to display the image group GG, the suction position deviation distribution AD, the suction position deviation shift graph AG, and the suction level shift graph ALG with a focus on a mounting head 251 which is the same as the mounting head 251 involved in a component suction in which a suction error occurs, i.e., a mounting head 251 having the same head information D12 as the mounting head 251 directed to the occurrence of the suction error. When the “suction nozzle” is designated as a target subject, the display control part 47 controls the mounting display part 50 to display the image group GG, the suction position deviation distribution AD, the suction position deviation shift graph AG, and the suction level shift graph ALG with a focus on a suction nozzle 251a which is the same as the suction nozzle 251a involved in a component suction in which a suction error occurs, i.e., a suction nozzle 251a having the same nozzle information D13 as the suction nozzle 251a directed to the occurrence of the suction error. When the “feeder” is designated as a target subject, the display control part 47 controls the mounting display part 50 to display the image group GG, the suction position deviation distribution AD, the suction position deviation shift graph AG, and the suction level shift graph ALG with a focus on a feeder 24F which is the same as the feeder 24F involved in a component suction in which a suction error occurs, i.e., a feeder 24F having the same feeder information D14 as the feeder 24F involved in the component suction in which the suction error occurs.

In this case, the display control part 47 controls the mounting display part 50 to display a designation region associated with the designated target subject among the designation regions B1 to B4 in a display mode different from a display mode for the remaining designation regions. In the example, for instance, the “component” is designated as the target subject for a default setting. Therefore, the operator designates at least one of the head designation region B2, the nozzle designation region B3, and the feeder designation region B4 via the mounting manipulation part 51 to enable switching from the display screen image DS showing the image group GG, the suction position deviation distribution AD, the suction position deviation shift graph AG, and the suction level shift graph ALG for the “component” as the target subject to a display screen image DS showing an image group GG, a suction position deviation distribution AD, a suction position deviation shift graph AG, and a suction level shift graph ALG for a designated target subject.

The component, the mounting head 251, the suction nozzle 251a, and the feeder 24F involved in the component suction may cause a factor of an occurrence of the suction error directed to the component by the suction nozzle 251a. In other words, the posture of the component or the shape of the component supplied by the feeder 24F may affect the performance of sucking and holding the component by the suction nozzle 251a. An operational performance or an aging deterioration of each of the suction nozzle 251a and the mounting head 251 may also affect the performance of sucking and holding the component by the suction nozzle 251a. Under the circumstances, the operator changes a target subject through an input manipulation via the mounting manipulation part 51 and changes a display content of the display screen image DS to enable more reliable specifying of a factor of the occurrence of the suction error.

When the component is specified as causing a factor of the occurrence of the suction error directed to the component, the operator checks, for example, an input value of a parameter, such as an outer dimension of a component registered in the component information D11 in the board data BD. The operator then performs a data change operation of changing data of the component information D11 when the parameter of the component information D11 is wrongly input to remove the factor of the occurrence of the suction error.

When the mounting head 251 is specified as causing a factor of the occurrence of the suction error, the operator checks, for example, whether a suction available position set as a lowered position of the mounting head 251 at sucking of the component by the suction nozzle 251a is proper. When the suction available position set for the mounting head 251 is improper, the operator may adjust the suction available position set for the mounting head 251 to remove the factor of the occurrence of the suction error. When an aging deterioration is seen in the mounting head 251, the operator may replace the mounting head 251.

When the suction nozzle 251a is specified as causing a factor of the occurrence of the suction error, the operator may, for example, clean the suction nozzle 251a or replace the same to remove the factor of the occurrence of the suction error. As aforementioned (FIG. 7), when the factor of the occurrence of the suction error is attributed to the mismatching between the suction nozzle 251a and the component, the operator may perform a data change operation for changing the suction nozzle 251a for use in a component suction to a suction nozzle 251a of a different kind in consideration of a relation with the component to remove the factor of the occurrence of the suction error.

When the feeder 24F is specified as causing a factor of the occurrence of the suction error, for example, the operator may replace the feeder 24F to remove the factor of the occurrence of the suction error.

As aforementioned (FIG. 6), when a relative deviation of a target suction position by the suction nozzle 251a in a component suction to a component supply position of the feeder 24F is specified as causing a factor of the occurrence of the suction error, the operator performs a data change operation of changing data of the target suction position information DAP to remove the factor of the occurrence of the suction error.

Modifications

The component mounting system 100 described heretofore shows an example of a preferable embodiment of a component mounting system according to the present disclosure, and a specific configuration is appropriately changeable in a range without deviation from the gist of the present disclosure. For instance, configurations described in the following items (1) to (6) and any configuration in appropriate combination among the configurations in items (1) to (6) belong to the present disclosure.

(1) In the embodiment, the mounter 10 includes the processing data storage part 40Mb. The management data DM is once stored in the processing data storage part 40Mb and is thereafter sent to the management device 12. However, the processing data storage part 40Mb may be excluded, and the management data DM may be directly sent from the mounter 10 or the mounting controller 4 to the management device 12, and accumulated and stored in the management storage part 124 of the management device 12. In this case, the display control part 47 reads out necessary management data DM from the management storage part 124 of the management device 12 in response to an input of a display request from an operator via the mounting manipulation part 51, and controls the mounting display part 50 to display, on the basis of the management data DM, the display screen image DS shown in FIG. 5. In this configuration, the management storage part 124 of the management device 12 serves as the “storage part” in the present disclosure.

(2) When a suction error directed to the component occurs in the configuration in item (1) excluding the processing data storage part 40Mb, for example, the management controller 125 may be configured to cause the management display part 122 to display a display screen image DS as shown in FIG. 5 on the basis of the management data DM stored in the management storage part 124 in response to an input of a display request from an operator via the management manipulation part 123 of the management device 12. This configuration allows the operator to specify a factor of the occurrence of the suction error while seeing the display screen image DS in the management device 12 at a remote location from the mounter 10. In this case, the management storage part 124, the management display part 122, and the management controller 125 respectively serve as the “storage part”, the “display part”, and the “display control part” in the present disclosure. Moreover, the management manipulation part 123 serves as the “instruction input part” in the present disclosure.

(3) Although not mentioned in the embodiment, as shown in FIG. 1, data on the display screen image DS may be transmitted to a mobile terminal 60 like a tablet computer via the communication control part 41, and the display control part 47 may be configured to cause a terminal display part 61 included in the mobile terminal 60 to display the display screen image DS. In this case, the terminal display part 61 of the mobile terminal 60 serves as the “display part” in the present disclosure.

(4) In the embodiment, when a suction error directed to a component occurs, the display screen image DS (FIG. 5) to assist in specifying of a factor of the occurrence of the suction error is displayed in response to an input manipulation of a display request from an operator via the mounting manipulation part 51. However, the screen image may be automatically displayed in an occurrence of a suction error without depending on the input manipulation by the operator. That is to say, the display control part 47 may be configured to control the mounting display part 50 to display the display screen image DS in synchronization with suspension of a component mounting process in the mounter main body 2, i.e., in conjunction with suspension of activation of the feeder 24F by the component supply control part 43 and suspension of activation of the head unit 25 by the head control part 44, in an occurrence of the suction error.

(5) In the embodiment, regarding an image group GG on the display screen image DS (FIG. 5), the display control part 47 executes displaying of the image group GG1 (GG2) including the suction processing images G14 (G12) chronologically arrayed in a row in the left-right direction. However, a specific display mode for the image group GG is not limited to the embodiment. Briefly, any display mode is adoptable as long as most recent processing state images G1 showing a display subject are arrayed in a chronologically recognizable manner.

(6) Although the display control part 47 executes displaying of each of the image group GG1 of the suction processing images 14 and the image group GG2 of the second supply processing images G12 as the image group GG in the embodiment, the display control part may further execute displaying of an image group of first supply processing images G11 or third supply processing images G13. Further, it is unnecessary to display all the suction position deviation distribution AD, the suction position deviation shift graph AG, and the suction level shift graph ALG together with the image group GG, and information about any one of the distribution and graphs may be displayed.

The present disclosure described heretofore will be summarized below.

A component mounting system according one aspect of the present disclosure includes: a mounting execution part including: a feeder for performing a component supply of supplying a component; a mounting head having a suction nozzle for performing a component suction of sucking the component, and performing a component mount of mounting the component sucked by the suction nozzle on a board; and a photographing camera for acquiring a processing state image showing the component suction; a storage part that accumulates and stores management data including the processing state image showing the component suction; a display part that displays information about the management data; and a display control part that controls the display part. When a suction error occurs in the component suction of the component by the suction nozzle, the display control part controls the display part to display a plurality of processing state images that is most recent among processing state images showing past component suctions involving at least one of the component, the suction nozzle, the mounting head, and the feeder which are involved in the component suction of the component and are to be designated as target subjects.

In the component mounting system, when a suction error occurs, the display part displays most recent processing state images showing at least one of the component, the suction nozzle, the mounting head, and the feeder involved in the relevant component suction as a target subject. The most recent processing state images include, in many cases, useful information for specifying a factor of the occurrence of the suction error. Thus, a check of the most recent processing state images leads to a success in specifying a factor of the occurrence of the suction error.

In the component mounting system, the display control part controls the display part to chronologically display the processing state images that are most recent.

A chronological change in the processing state images shows useful information for specifying a factor of the occurrence of the suction error. The configuration hence contributes to the specifying of the factor of the suction error.

In the component mounting system, the management data associates parameter information specifying each of the component, the suction nozzle, the mounting head, and the feeder involved in the component suction with the processing state image showing the component suction. The component mounting system further includes an instruction input part that receives an input of an instruction about a display mode of the display part. When the display control part receives an instruction of designating one among the component, the suction nozzle, the mounting head, and the feeder as a target subject via the instruction input part, the display control part controls the display part to display the processing state images showing the designated target subject.

Each of the component, the mounting head, the suction nozzle, and the feeder involved in the component suction significantly corelates to a factor of the occurrence of the suction error. The configuration enables a change in the target subject by an input manipulation via the instruction input part to change a display content on the display screen image, and thus contributes to rapider specifying of a factor of the occurrence of the suction error.

In the component mounting system, the management data further includes suction position deviation data associated with the processing state image showing the component suction, the suction position deviation data indicating a deviation amount of a suction position of the component with respect to the suction nozzle in the component suction. The display control part controls the display part to display, together with the processing state images, a suction position deviation distribution showing a distribution according to a data group including the suction position deviation data.

This configuration succeeds in confirming, further on the basis of the suction position deviation distribution, a situation of an occurrence of a position deviation of an actual suction position of the target subject concurrently with checking the processing state images. The configuration hence contributes to narrowing-down of a factor of the occurrence of the suction error.

In this case, the display control part controls the display part to further display, together with the processing state images, a suction position deviation shift graph showing a chronological shift according to the data group including the suction position deviation data.

This configuration enables confirmation further based on the suction position deviation shift graph about a chronological shift of the position deviation. Hence, the configuration further contributes to narrowing-down of the factor of the suction error.

In the component mounting system, the management data further includes suction level data associated with the processing state image showing the component suction, the suction level data indicating a component suction level of the suction nozzle in the component suction. The display control part controls the display part to display, together with the processing state images, a suction level shift graph showing a chronological shift according to a data group including the suction level data indicating the component suction level.

This configuration succeeds in confirming, further on the basis of the suction level shift graph, a chronological shift of the suction level data concurrently with checking the processing state images. Hence, the configuration further contributes to narrowing-down of the factor of the suction error.

In the component mounting system, the display part is included in a mobile terminal. This configuration enables a check of the processing state image displayed on the display part of the mobile terminal simultaneously with an access to each element in the mounting execution part. Hence, the configuration achieves effective specifying of a factor of the occurrence of the suction error while allowing a visual check for each element in the mounting execution part.

1. A component mounting system, comprising:
a mounting execution machine including:
a feeder configured to perform a component supply of supplying a component;
a mounting head having a suction nozzle configured to perform a component suction of sucking the component, and configured to perform a component mount of mounting the component sucked by the suction nozzle on a board; and
a photographing camera configured to acquire a processing state image showing the component suction;
a storage configured to accumulate and store management data including the processing state image showing the component suction;
a display configured to display information about the management data; and
a display controller configured to control the display, wherein,
when a suction error occurs in the component suction of the component by the suction nozzle, the display controller is configured to control the display to display a plurality of processing state images that is most recent among processing state images showing past component suctions involving at least one of the component, the suction nozzle, the mounting head, and the feeder which are involved in the component suction of the component and are to be designated as target subjects.

2. The component mounting system according to claim 1, wherein
the display controller is configured to control the display to chronologically display the processing state images that are most recent.

3. The component mounting system according to claim 1, wherein the management data associates parameter information specifying each of the component, the suction nozzle, the mounting head, and the feeder involved in the component suction with the processing state image showing the component suction, the component mounting system further comprising:
an instruction input configured to receive an input of an instruction about a display mode of the display, wherein,
when the display controller receives an instruction of designating one among the component, the suction nozzle, the mounting head, and the feeder as a target subject via the instruction input, the display controller is configured to control the display to display the processing state images showing the designated target subject.

4. The component mounting system according to 1, wherein
the management data further includes suction position deviation data associated with the processing state image showing the component suction, the suction position deviation data indicating a deviation amount of a suction position of the component with respect to the suction nozzle in the component suction, and
the display controller is configured to control the display to display, together with the processing state images, a suction position deviation distribution showing a distribution according to a data group including the suction position deviation data.

5. The component mounting system according to claim 4, wherein the display controller is configured to control the display to further display, together with the processing state images, a suction position deviation shift graph showing a chronological shift according to the data group including the suction position deviation data.

6. The component mounting system according to claim 1, wherein
the management data further includes suction level data associated with the processing state image showing the component suction, the suction level data indicating a component suction level of the suction nozzle in the component suction, and
the display controller is configured to control the display to display, together with the processing state images, a suction level shift graph showing a chronological shift according to a data group including the suction level data indicating the component suction level.

7. The component mounting system according to claim 1, wherein the display is in a mobile terminal.

8. The component mounting system according to claim 2, wherein the management data associates parameter information specifying each of the component, the suction nozzle, the mounting head, and the feeder involved in the component suction with the processing state image showing the component suction, the component mounting system further comprising:
an instruction input configured to receive an input of an instruction about a display mode of the display, wherein,
when the display controller receives an instruction of designating one among the component, the suction nozzle, the mounting head, and the feeder as a target subject via the instruction input, the display controller is configured to control the display to display the processing state images showing the designated target subject.

9. The component mounting system according to claim 2, wherein
the management data further includes suction position deviation data associated with the processing state image showing the component suction, the suction position deviation data indicating a deviation amount of a suction position of the component with respect to the suction nozzle in the component suction, and
the display controller is configured to control the display to display, together with the processing state images, a suction position deviation distribution showing a distribution according to a data group including the suction position deviation data.

10. The component mounting system according to claim 3, wherein
the management data further includes suction position deviation data associated with the processing state image showing the component suction, the suction position deviation data indicating a deviation amount of a suction position of the component with respect to the suction nozzle in the component suction, and
the display controller is configured to control the display to display, together with the processing state images, a suction position deviation distribution showing a distribution according to a data group including the suction position deviation data.

11. The component mounting system according to claim 8, wherein
the management data further includes suction position deviation data associated with the processing state image showing the component suction, the suction position deviation data indicating a deviation amount of a suction position of the component with respect to the suction nozzle in the component suction, and
the display controller is configured to control the display to display, together with the processing state images, a suction position deviation distribution showing a distribution according to a data group including the suction position deviation data.

12. The component mounting system according to claim 2, wherein
the management data further includes suction level data associated with the processing state image showing the component suction, the suction level data indicating a component suction level of the suction nozzle in the component suction, and
the display controller is configured to control the display to display, together with the processing state images, a suction level shift graph showing a chronological shift according to a data group including the suction level data indicating the component suction level.

13. The component mounting system according to claim 3, wherein
the management data further includes suction level data associated with the processing state image showing the component suction, the suction level data indicating a component suction level of the suction nozzle in the component suction, and
the display controller is configured to control the display to display, together with the processing state images, a suction level shift graph showing a chronological shift according to a data group including the suction level data indicating the component suction level.

14. The component mounting system according to claim 4, wherein
the management data further includes suction level data associated with the processing state image showing the component suction, the suction level data indicating a component suction level of the suction nozzle in the component suction, and
the display controller is configured to control the display to display, together with the processing state images, a suction level shift graph showing a chronological shift according to a data group including the suction level data indicating the component suction level.

15. The component mounting system according to claim 5, wherein
the management data further includes suction level data associated with the processing state image showing the component suction, the suction level data indicating a component suction level of the suction nozzle in the component suction, and
the display controller is configured to control the display to display, together with the processing state images, a suction level shift graph showing a chronological shift according to a data group including the suction level data indicating the component suction level.

16. The component mounting system according to claim 2, wherein the display is in a mobile terminal.

17. The component mounting system according to claim 3, wherein the display is in a mobile terminal.

18. The component mounting system according to claim 4, wherein the display is in a mobile terminal.

19. The component mounting system according to claim 5, wherein the display is in a mobile terminal.

20. The component mounting system according to claim 6, wherein the display is in a mobile terminal.
